(19) United States
(12) Patent Application Publication
(10) Pub. No.: US 2024/0405750 A1
(43) Pub. Date: Dec. 5, 2024

(54) PACKAGED ACOUSTIC WAVE DEVICES WITH MULTILAYER PIEZOELECTRIC SUBSTRATE

(71) Applicant: SKYWORKS SOLUTIONS, INC., Irvine, CA (US)

(72) Inventors: Rei Goto, Osaka-Shi (JP); Hironori Fukuhara, Ibaraki-Shi (JP); Atsushi Takano, Kadoma-Shi (JP)

(21) Appl. No.: 18/664,831

(22) Filed: May 15, 2024

Related U.S. Application Data
(60) Provisional application No. 63/470,226, filed on Jun. 1, 2023.

(51) Int. Cl. H03H 9/64; H03H 3/08

(52) U.S. Cl. CPC H03H 9/6489; H03H 3/08; H03H 9/6483

(57) ABSTRACT

Aspects and embodiments disclosed herein include a packaged acoustic wave component comprising a base layer, an acoustic wave filter disposed on an upper side of the base layer, a cap layer mounted to the upper side of the base layer such that a bottom side of the cap layer faces the upper side of the base layer, and an electrical shield layer disposed on the bottom side of the cap layer such that the electrical shield layer and the acoustic wave filter are positioned between the base layer and the cap layer.

### CROSS-REFERENCE TO RELATED APPLICATIONS

This application claims priority under 35 U.S.C. § 119 (e) to U.S. Provisional Patent Application Ser. No. 63/470,226, titled “PACKAGED ACOUSTIC WAVE DEVICES WITH MULTILAYER PIEZOELECTRIC SUBSTRATE,” filed Jun. 1, 2023, the entire content of which is incorporated herein by reference for all purposes.

### BACKGROUND

### Field

Aspects and embodiments disclosed herein relate to acoustic wave devices, in particular to packaged acoustic wave components, which may also be designated as acoustic wave component packages.

### Description of the Related Technology

An acoustic wave filter can include a plurality of resonators arranged to filter a radio frequency signal. Example acoustic wave resonators include surface acoustic wave (SAW) resonators and bulk acoustic wave (BAW) resonators. A surface acoustic wave resonator can include an interdigital transductor electrode disposed on a piezoelectric substrate. The surface acoustic wave resonator can generate a surface acoustic wave on a surface of the piezoelectric substrate on which the interdigital transducer electrode is disposed. A multi-mode SAW filter can include a plurality of longitudinally coupled interdigital transducer electrodes positioned between acoustic reflectors. In BAW resonators, acoustic waves propagate in the bulk of a piezoelectric layer. Examples of BAW resonators include film bulk acoustic wave resonators and solidly mounted resonators (SMRs).

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, three acoustic wave filters can be arranged as a triplexer. As another example, four acoustic wave filters can be arranged as a quadplexer.

Acoustic wave filters with small package sizes are generally desirable. However, decreasing the size of an acoustic wave filter can be challenging. The packaging process for multilayer piezoelectric substrate packages with acoustic wave devices can apply stresses to the piezoelectric layer (e.g., during heat cycle testing) that can result in reliability issues including cracking of the piezoelectric layer.

### SUMMARY

Accordingly, there is a need for a packaged acoustic wave component, in particular a surface acoustic wave (e.g., SAW or TCSAW) package with improved reliability that can withstand the stresses (e.g., from heat cycle testing) during the packaging process.

The innovations described in the claims each have several aspects, no single one of which is solely responsible for its desirable attributes. Without limiting the scope of the claims, some prominent features of this disclosure will now be briefly described.

In a first aspect, a packaged acoustic wave component is disclosed. The packaged acoustic wave component includes a base layer and an acoustic wave filter disposed on an upper side of the base layer. The packaged acoustic wave component also includes a cap layer mounted to the upper side of the base layer such that a bottom side of the cap layer faces the upper side of the base layer as well as an electrical shield layer disposed on the bottom side of the cap layer such that the electrical shield layer and the acoustic wave filter are positioned between the base layer and the cap layer.

Such a packaged acoustic wave component provides a strong grounded electrical shield for the functionality of the acoustic wave filter.

In some embodiments, the base layer is configured as a base wafer.

In some embodiments, the cap layer is configured as a cap wafer.

In some embodiments, the packaged acoustic wave component further comprises a seal ring disposed on the bottom side of the cap layer around the electrical shield layer.

In some embodiments, the seal ring of the cap layer and the electrical shield layer are made of the same material.

In some embodiments, the seal ring of the cap layer is electrically connected to the electrical shield layer.

In some embodiments, the packaged acoustic wave component further comprises a seal ring disposed on the upper side of the base layer around the acoustic wave filter.

In some embodiments, the seal ring of the base layer is electrically connected to the acoustic wave filter.

In some embodiments, the packaged acoustic wave component further comprises a support pillar coupling the seal ring of the base layer with the seal ring of the cap layer.

In some embodiments, the cap layer comprises at least one of silicon, quartz, glass, spinel, or sapphire.

In some embodiments, the electrical shield layer is formed as a grid pattern.

In some embodiments, the acoustic wave filter is configured as a surface acoustic wave (SAW) filter.

In some embodiments, the acoustic wave filter is configured as a temperature compensated surface acoustic wave (TCSAW) filter.

In some embodiments, the acoustic wave filter is configured as a bulk acoustic wave (BAW) filter.

Moreover, aspects and embodiments disclosed herein include a method for providing (or forming) such a packaged acoustic wave component. The method of making a packaged acoustic wave component comprises forming a base layer, forming an acoustic wave filter disposed on an upper side of the base layer, forming a cap layer for mounting to the upper side of the base layer such that a bottom side of the cap layer faces the upper side of the base layer, and forming an electrical shield layer disposed on the bottom side of the cap layer such that the electrical shield layer and the acoustic wave filter are positioned between the base layer and the cap layer.

In some embodiments, the method further comprises forming a seal ring disposed on the bottom side of the cap layer around the electrical shield layer after forming or providing the electrical shield layer.

In a second aspect, a radio frequency module is disclosed. The radio frequency module includes a packaged acoustic wave component. The packaged acoustic wave component includes a base layer and an acoustic wave filter disposed on an upper side of the base layer. The packaged acoustic wave component also includes a cap layer mounted to the upper side of the base layer such that a bottom side of the cap layer faces the upper side of the base layer. The packaged acoustic wave component also includes an electrical shield layer disposed on the bottom side of the cap layer such that the electrical shield layer and the acoustic wave filter are positioned between the base layer and the cap layer.

In some embodiments, the radio frequency module is configured as a front end module.

In a third aspect, a wireless communication device is disclosed. The wireless communication device includes a radio frequency module comprising a packaged acoustic wave component. The packaged acoustic wave component includes a base layer and an acoustic wave filter disposed on an upper side of the base layer. The packaged acoustic wave component also includes a cap layer mounted to the upper side of the base layer such that a bottom side of the cap layer faces the upper side of the base layer and includes an electrical shield layer disposed on the bottom side of the cap layer such that the electrical shield layer and the acoustic wave filter are positioned between the base layer and the cap layer.

In some embodiments, the wireless communication device further comprises an antenna operatively connected to the acoustic wave filter.

In some embodiments, the wireless communication device further comprises a radio frequency amplifier operatively coupled to the radio frequency module and configured to amplify the radio frequency signal.

In some embodiments, the wireless communication device further comprises a transceiver in communication with the radio frequency amplifier.

In some embodiments, the wireless communication device further comprises a baseband processor in communication with the transceiver.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A is a simplified plan view of a bottom side of a cap layer of a packaged acoustic wave component according to an embodiment;

FIG. 1B is a simplified plan view of an upper side of a base layer of a packaged acoustic wave component according to an embodiment;

FIG. 1C is a cross-sectional view of a packaged acoustic wave component according to an embodiment;

FIG. 1D is a simplified plan view of a bottom side of a cap layer of a packaged acoustic wave component according to another embodiment;

FIG. 1E is a simplified plan view of an upper side of a base layer of a packaged acoustic wave component according to another embodiment;

FIG. 1F is a cross-sectional view of a packaged acoustic wave component according to another embodiment;

FIG. 2 is a perspective view of a packaged acoustic wave component that includes an electrical shield layer formed as a grid pattern according to an embodiment;

FIG. 3 is a graph showing simulated frequency responses of the packaged acoustic wave component of FIGS. 1A, 1B, 1C and 2 in comparison to packaged acoustic wave components without an electrical shield layer;

FIG. 4A is a schematic diagram of a transmit filter that includes a surface acoustic wave resonator according to an embodiment;

FIG. 4B is a schematic diagram of a receive filter that includes a surface acoustic wave resonator according to an embodiment;

FIG. 5 is a schematic diagram of a radio frequency module that includes a surface acoustic wave resonator according to an embodiment;

FIG. 6 is a schematic diagram of a radio frequency module that includes filters with surface acoustic wave resonators according to an embodiment;

FIG. 7 is a schematic block diagram of a module that includes an antenna switch and duplexers that include a surface acoustic wave resonator according to an embodiment;

FIG. 8A is a schematic block diagram of a module that includes a power amplifier, a radio frequency switch, and duplexers that include a surface acoustic wave resonator according to an embodiment;

FIG. 8B is a schematic block diagram of a module that includes filters, a radio frequency switch, and a low noise amplifier according to an embodiment;

FIG. 9A is a schematic block diagram of a wireless communication device that includes a filter with a surface acoustic wave resonator in accordance with one or more embodiments;

FIG. 9B is a schematic block diagram of another wireless communication device that includes a filter with a surface acoustic wave resonator in accordance with one or more embodiments; and

FIG. 10 illustrates a method of making a packaged acoustic wave component according to an embodiment.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of implementations, such as in an RF front end of a mobile phone. An acoustic wave filter can be implemented with surface acoustic wave (SAW) devices. SAW devices include SAW resonators, SAW delay lines, and multi-mode SAW (MMS) filters (e.g., double mode SAW (DMS) filters). Any features of the SAW resonators and/or devices discussed herein can be implemented in any suitable SAW device.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors.

Multi-layer piezoelectric substrate (MPS) SAW resonators can thermally insulate an interdigital transducer electrode and a piezoelectric layer. By reducing dissipative thermal impedance of the SAW device, the ruggedness and power handling can be improved. Furthermore, MPS SAW resonators can comprise a high power durability filter solution.

Some MPS SAW resonators have achieved a desired filter performance by module level shielding. However, such approaches have encountered technical challenges related to ineffective electrical coupling on multi-chip module (MCM) devices, for example, filter and inductor coupling.

Some other MPS SAW resonators packages have achieved a desired filter performance by utilizing packaging structures like chip scale packaging (CSP) or solder hermetic packaging structures. However, such approaches have exhibited relatively large sizes of the packaged MPS SAW resonators.

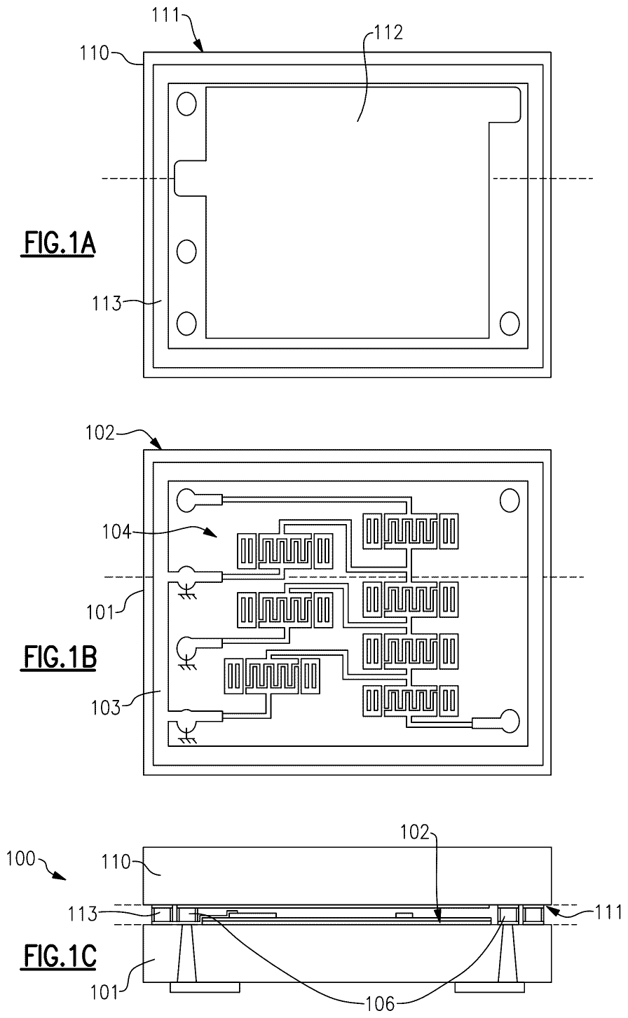

FIGS. 1A, 1B, and 1C illustrate a packaged acoustic wave component 100 (e.g., a multi-layer piezoelectric substrate (MPS) package or structure) according to an embodiment. FIG. 1A illustrates a simplified plan view of a bottom side 111 of a cap layer 110 of the packaged acoustic wave component 100. FIG. 1B illustrates a simplified plan view of an upper side 102 of a base layer 101 of the packaged acoustic wave component 100. FIG. 1C illustrates a cross-sectional view through the packaged acoustic wave component 100. In some embodiments, the base layer 101 can be a base wafer (e.g., a device wafer), and the cap layer 110 can be a cap wafer.

The packaged acoustic wave component 100 has a base wafer 101 comprising an upper side 102. An acoustic wave filter 104 is disposed on the upper side of the base wafer 101. For example, the base wafer 101 can comprise a piezoelectric layer (e.g., a lithium niobate (LN or LiNbO₃) layer or a lithium tantalate (LT or LiTaO₃) layer) and an interdigital transducer (IDT) electrode over the piezoelectric layer. Such packaged acoustic wave components 100 can also include a temperature compensation layer (e.g., a silicon dioxide (SiO₂) layer) over the IDT electrode in certain embodiments. The acoustic wave filter 104 can be configured as a surface acoustic wave (SAW) filter, as a temperature compensated surface acoustic wave (TCSAW) filter, or as a bulk acoustic wave (BAW) filter.

The packaged acoustic wave component 100 also has a cap wafer 110 comprising a bottom side 111. An electrical shield layer 112 is disposed on the bottom side 111 of the cap wafer 110.

The packaged acoustic wave component 100 can further comprise a seal ring 113 (or ring structure), as shown in FIG. 1A. The seal ring 113 can be formed over the cap wafer 110 such that the seal ring 113 is electrically connected to the bottom side 111 of the cap wafer 110. The seal ring 113 may be formed in a rectangular shape, but is not limited to such a shape. Alternatively, the seal ring 113 can be formed in a circular or similar shape or such that it corresponds to the outer rim of the bottom side 111 of the cap wafer 110. FIG. 1A shows that the seal ring 113 encloses the electrical shield layer 112.

In some embodiments, the MPS is configured to form a ring structure 113 on the cap wafer 110, the ring structure 113 defining an inner area dimensioned to accommodate the electrical shield layer 112. The seal ring 113 is further configured to allow mounting of the base wafer 101 to substantially enclose the inner area.

The seal ring 113 of the cap wafer 110 and the electrical shield layer 112 are made of the same material in some embodiments. The seal ring 113 of the cap wafer 110 may be made of copper, but can be also made of other electrically conductive materials. Furthermore, the seal ring 113 can be electrically connected to the electrical shield layer 112 to support the cap wafer 110 and the base wafer 101.

The packaged acoustic wave component 100 can further comprise a seal ring 103 (or ring structure), as shown in FIG. 1B. The seal ring 103 can be formed over the base wafer 101 such that the seal ring 103 is electrically connected to the upper side 102 of the base wafer 101. The seal ring 103 is formed in a rectangular shape in some embodiments, but is not limited to such a shape. Alternatively, the seal ring 103 can be formed in a circular or similar shape or such that it corresponds to the outer rim of the upper side 102 of the base wafer 101. The seal ring 103 can enclose the acoustic wave filter 104. Moreover, the seal ring 103 can be electrically coupled to the acoustic wave filter 104. The seal ring 103 of the base wafer 101 may be made of copper, but can be also made of other electrically conductive materials.

In some embodiments, the MPS is configured to form a ring structure 103 on the base wafer 101, the ring structure 103 defining an inner area dimensioned to accommodate the acoustic wave filter 104. The seal ring 103 is further configured to allow mounting of the base wafer 101 to substantially enclose the inner area.

In FIG. 1C, the cap wafer 110 is mounted or attached with its bottom side 111 to the upper side 102 of the base wafer 101. Hence, the bottom side 111 of the cap wafer 110 faces the upper side 102 of the base wafer 101. That means, that the electrical shield layer 112 and the acoustic wave filter 104 are positioned between the base wafer 101 and the cap wafer 110. For mounting the cap wafer 110 on the base wafer 101 a support pillar 106 can be provided disposed between the base wafer 101 and the cap wafer 110. In some embodiments, the seal ring 113 and one or more support pillars 106 are formed on the cap wafer 110. Optionally, at least one support pillar 106 can also be provided to electrically connect an electrode of the base wafer 101 or of the acoustic wave filter 104 with an electrode of the cap wafer 110.

Although the base wafer 101 in FIG. 1C is depicted as having the same lateral size as the cap wafer 110, it will be understood that the base wafer 101 can be larger and can include one or more other components mounted thereon.

In some embodiments, the base wafer 101, the cap wafer 110 and the support pillar 106 can form a hermetic cavity structure implemented on the base layer 101. Such a base wafer 101 can include one or more circuits. A stacked layout of the packaged acoustic wave component 100 is shown in FIG. 1C to surround an inner area. Such a stacked layout can include one or more features as described herein. Such an inner area can be dimensioned to allow implementation of one or more devices (depicted as 104) therein. Such a device may be built on or be a part (e.g., a MEMS device) of the acoustic wave filter 104 of the base wafer 101, may be a separate device (e.g., a SAW or BAW) that is attached to the upper side 102 of the base wafer 101, or any combination thereof.

In some embodiments, a cap layer 110 such as a wafer is provided to be mounted on the base wafer 101 to enclose the inner area into a hermetically sealed cavity. Such a cap wafer may be configured to provide sealing functionality, may contain one or more circuits configured to perform some desired function in conjunction with the base wafer, or any combination thereof.

Advantageously, the packaged acoustic wave component 100 improves at least one of electrical isolation, rejection, or attenuation. This results in improved reliability and mechanical ruggedness of the packaged acoustic wave component 100. Furthermore, the filter performance of the packaged acoustic wave component 100 is less influenced by impacts of the external environment. It also allows for a size reduction by less filter stage in the packaged acoustic wave component 100, as described above.

FIGS. 1D, 1E, and IF illustrate a packaged acoustic wave component 100 (e.g., a multi-layer piezoelectric substrate (MPS) package or structure) according to another embodiment. FIG. 1D illustrates a simplified plan view of a bottom side 111 of a cap layer 110 of the packaged acoustic wave component 100. FIG. 1E illustrates a simplified plan view of an upper side 102 of a base layer 101 of the packaged acoustic wave component 100. FIG. 1F illustrates a cross-sectional view through the packaged acoustic wave component 100. In some embodiments, the base layer 101 can be a base wafer (e.g., a device wafer), and the cap layer 110 can be a cap wafer.

The packaged acoustic wave component 100 of FIGS. 1D, 1E, and IF has basically the same features as described with respect to that of FIGS. 1A, 1B, and 1C. The component 100 of FIGS. 1D, 1E, and IF differs in that the cap wafer 110 comprises a ground inductor 114 as illustrated in FIG. 1D.

In some embodiments, the ground inductor 114 is formed where the shield electrode is formed. By providing the ground inductor, the attenuation characteristic of the filter can be improved. Furthermore, an external inductor can be removed.

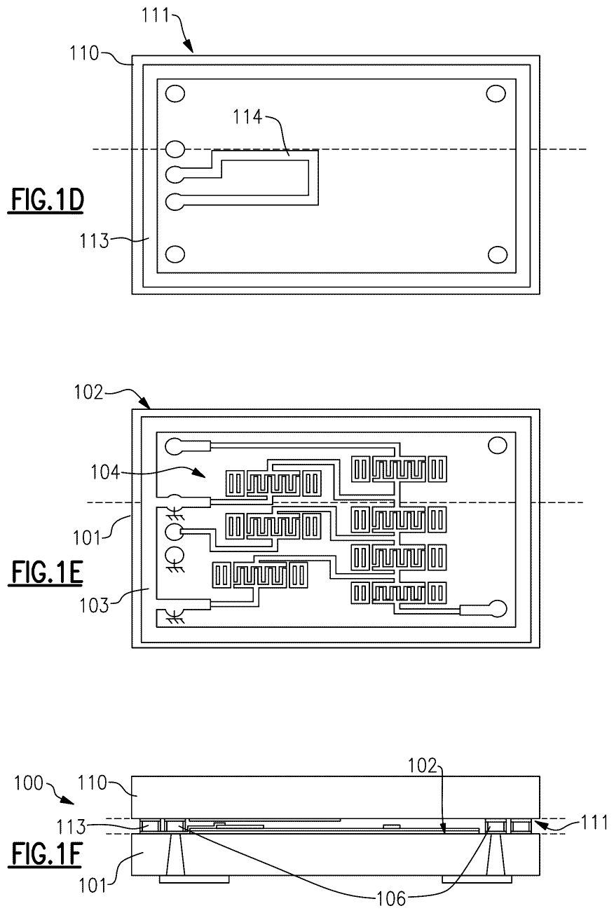

FIG. 2 shows a perspective view of a packaged acoustic wave component 200 that includes an electrical shield layer 112 formed as a grid pattern 112a according to an embodiment. The packaged acoustic wave component 200 comprises the same features as the packaged acoustic wave component 100 according to FIGS. 1A-1C.

The packaged acoustic wave component 200 differs from the component 100 in that the electrical shield layer 112 comprises the grid pattern 112a, as illustrated in FIG. 2. In some embodiments, the grid pattern 112a has a rectangular layout, but is not limited to such a layout, and can alternatively have a circular, an oval, or combined layout.

Advantageously, by arranging the shield electrode (or the electrode to which the electrical shield layer 112 is connected to) near the signal line on the piezoelectric layer, a capacitance is generated from the signal line to the shield electrode. When the capacitance is large, the electromechanical coupling coefficient of the piezoelectric element appears equivalently small, which may change the input impedance of the filter such as the acoustic wave component 100. Electrostatic coupling between the signal line on the piezoelectric layer and the shield electrode can be reduced by using the grid-shaped electrodes.

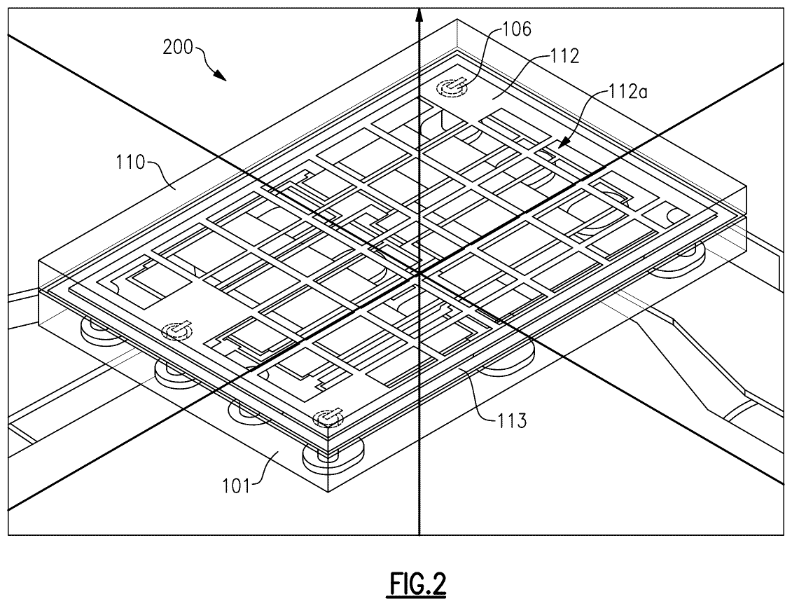

FIG. 3 is a graph showing simulated frequency responses of the packaged acoustic wave component 100, 200 of FIGS. 1A, 1B, 1C, and 2 in comparison to packaged acoustic wave components without an electrical shield layer. In the graph, there are plotted four different combinations of the features seal rings 103, 113 and electrical shield layer 112. The continuous line represents the frequency response of a packaged acoustic wave component having a seal ring which is not grounded and without an electrical shield layer. The dashed line represents the frequency response of a packaged acoustic wave component having a seal ring which is not grounded and with an electrical shield layer 112 according to an embodiment described herein. The dotted line represents the frequency response of a packaged acoustic wave component having a seal ring which is grounded and without an electrical shield layer. Finally, the dashed-dotted line represents the frequency response of a packaged acoustic wave component having a seal ring which is grounded and with an electrical shield layer 112 comprising a grid pattern layout according to an embodiment described herein.

FIG. 3 clearly illustrates that providing an electrical shield layer 112 in a MPS device improves the electrical attenuation/rejection. Furthermore, it can be seen that the combination of an electrical shield layer 112 having a grid pattern layout 112a with a grounded seal ring 103, 113 can result in the best filter performance.

An MPS acoustic wave resonator or device or die in a packaged acoustic wave component, including any suitable combination of features disclosed herein, can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more MPS acoustic wave resonators disclosed herein. FR1 can be from 410 MHz to 7.125 GHZ, for example, as specified in a current 5G NR specification. In 5G applications, the thermal dissipation of the MPS acoustic wave resonators disclosed herein can be advantageous For example, such thermal dissipation can be desirable in 5G applications with a higher time-division duplexing (TDD) duty cycle compared to fourth generation (4G) Long Term Evolution (LTE). One or more MPS acoustic wave resonators in accordance with any suitable principles and advantages disclosed herein can be included in a filter arranged to filter a radio frequency signal in a 4G LTE operating band and/or in a filter having a passband that includes a 4G LTE operating band and a 5G NR operating band.

Another aspect of the present disclosure includes a radio-frequency (RF) apparatus including a base wafer having an integrated circuit (IC) configured to provide RF functionality and a cap wafer implemented over the base wafer. The RF apparatus includes a seal ring implemented to join the cap wafer to the base wafer to yield a hermetic cavity. The seal ring includes a pad. The pad includes a polymer layer having a side that forms an interface with another layer of the pad. The pad further includes an upper metal layer having an upper side over the interface. The seal ring further includes a passivation layer implemented over the upper metal layer. The passivation layer includes a pattern configured to provide a compressive force on the upper metal layer to reduce the likelihood of delamination at the interface. The pattern defines a plurality of openings to expose the upper side of the upper metal layer. The seal ring further includes a metal structure implemented over the pad such that the metal structure is connected to the exposed upper side of the upper metal layer through the plurality of openings of the passivation layer.

In some embodiments, the cap wafer of the RF apparatus includes an IC, and in some embodiments, the IC of the cap wafer is at least partially connected electrically to the IC of the base wafer through the seal ring. In some implementations, the RF apparatus further includes a device implemented within the hermetic cavity.

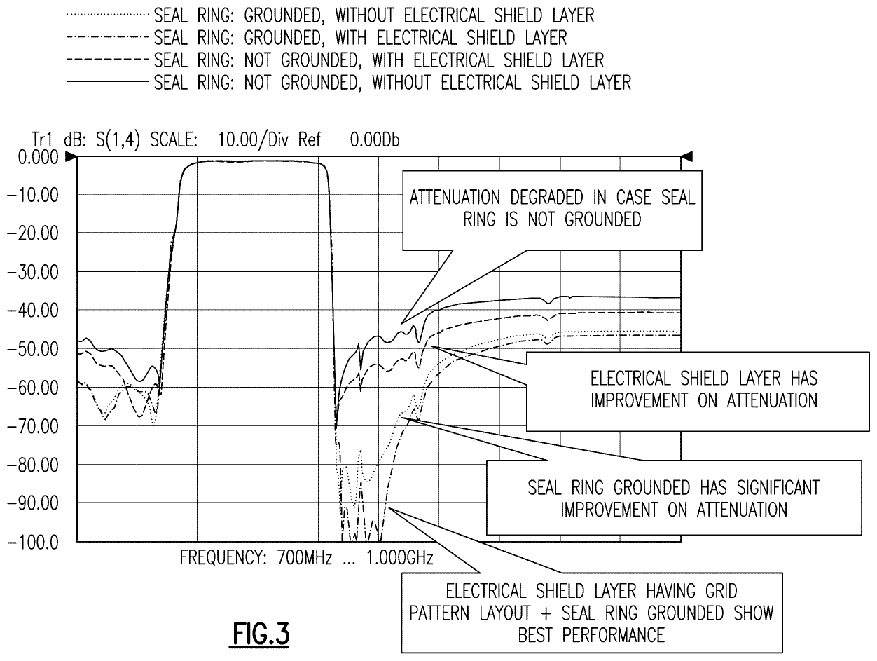

FIG. 4A is a schematic diagram of an example transmit filter 141 that includes packaged surface acoustic wave resonators according to an embodiment. The transmit filter 141 can be a band pass filter. The illustrated transmit filter 141 is arranged to filter a radio frequency signal received at a transmit port TX and provide a filtered output signal to an antenna port ANT. Some or all of the SAW resonators TS1 to TS7 and/or TP1 to TP5 can be a SAW resonator in accordance with any suitable principles and advantages disclosed herein. For instance, one or more of the SAW resonators of the transmit filter 141 can be part of one or more of the packaged acoustic wave components such as the packaged acoustic wave components 100, 200 of any of FIGS. 1A, 1B, 1C, and 2. Any suitable number of series SAW resonators and shunt SAW resonators can be included in a transmit filter 141.

FIG. 4B is a schematic diagram of a receive filter 145 that includes surface acoustic wave resonators according to an embodiment. The receive filter 145 can be a band pass filter. The illustrated receive filter 145 is arranged to filter a radio frequency signal received at an antenna port ANT and provide a filtered output signal to a receive port RX. Some or all of the SAW resonators RS1 to RS8 and/or RP1 to RP6 can be SAW resonators included in a packaged acoustic wave component in accordance with any suitable principles and advantages disclosed herein. For instance, one or more of the SAW resonators of the receive filter 145 can be part of one or more of the packaged acoustic wave components 100, 200 of any of FIGS. 1A, 1B, 1C, and 2. Any suitable number of series SAW resonators and shunt SAW resonators can be included in the receive filter 145.

Although FIGS. 4A and 4B illustrate example ladder filter topologies, any suitable filter topology can include a SAW resonator in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

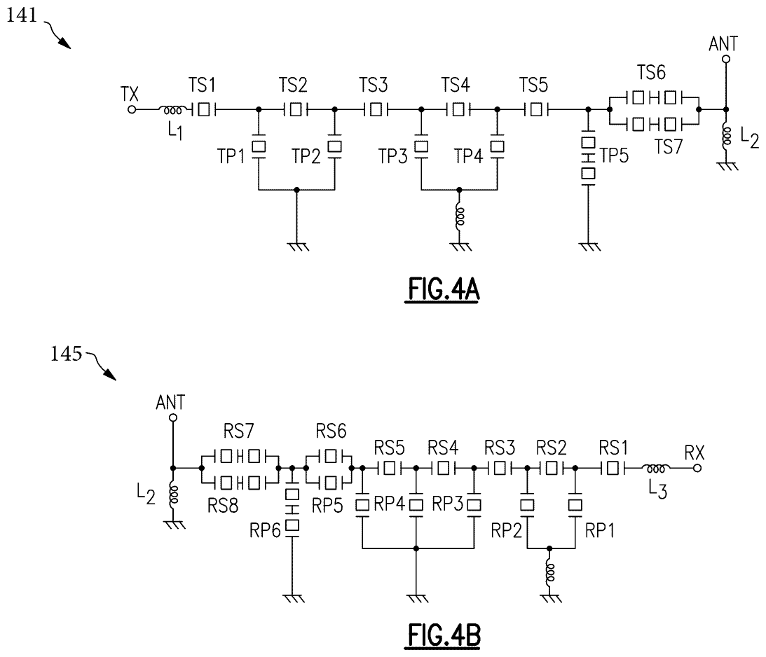

FIG. 5 is a schematic diagram of a radio frequency module 175 that includes a surface acoustic wave component 176 according to an embodiment. The illustrated radio frequency module 175 includes the SAW component 176 and other circuitry 177. The SAW component 176 can include one or more SAW resonators with any suitable combination of features of the SAW resonators or packages disclosed herein. The SAW component 176 can include a SAW die that includes SAW resonators.

The SAW component 176 shown in FIG. 5 includes a filter 178 and terminals 179A and 179B. The filter 178 includes SAW resonators. One or more of the SAW resonators can be implemented in accordance with any suitable principles and advantages of the packaged acoustic wave components 100, 200 of any of FIGS. 1A-2. The terminals 179A and 179B can serve, for example, as an input contact and an output contact. The SAW component 176 and the other circuitry 177 are on the same packaging substrate 180 in FIG. 5. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

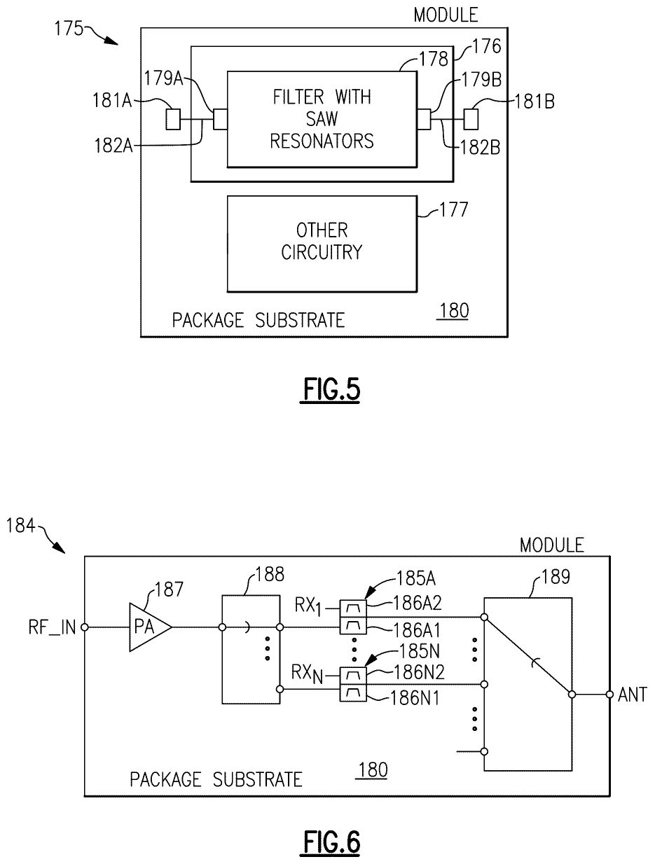

FIG. 6 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on the same packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators or packages in accordance with any suitable principles and advantages disclosed herein. Similarly, one or more of the receive filters 186A2 to 186N2 can include one or more SAW resonators in accordance with any suitable principles and advantages disclosed herein. Although FIG. 6 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

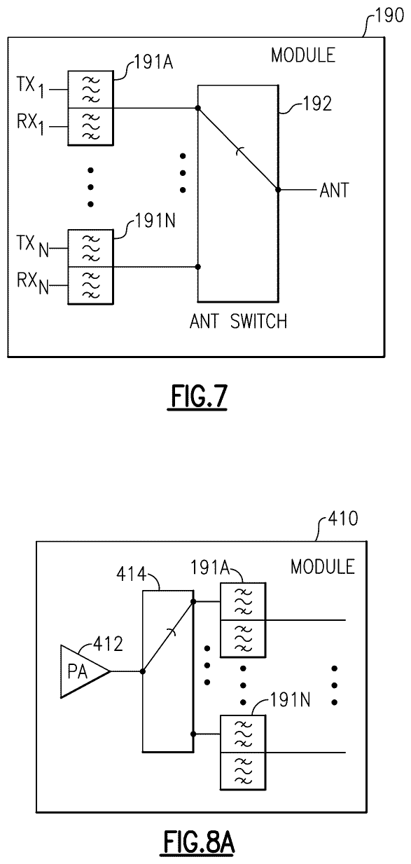

FIG. 7 is a schematic block diagram of a module 190 that includes duplexers 191A to 191N and an antenna switch 192. One or more filters of the duplexers 191A to 191N can include any suitable number of surface acoustic wave resonators or packages in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

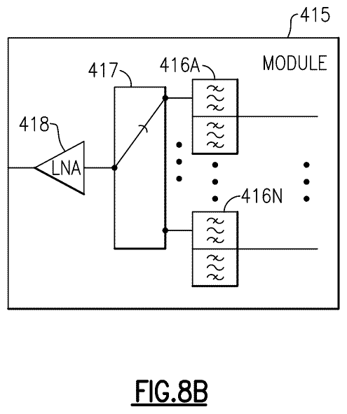

FIG. 8A is a schematic block diagram of a module 410 that includes a power amplifier 412, a radio frequency switch 414, and duplexers 191A to 191N in accordance with one or more embodiments. The power amplifier 412 can amplify a radio frequency signal. The radio frequency switch 414 can be a multi-throw radio frequency switch. The radio frequency switch 414 can electrically couple an output of the power amplifier 412 to a selected transmit filter of the duplexers 191A to 191N. One or more filters of the duplexers 191A to 191N can include any suitable number of surface acoustic wave resonators or packages in accordance with any suitable principles and advantages discussed herein. Any suitable number of duplexers 191A to 191N can be implemented.

FIG. 8B is a schematic block diagram of a module 415 that includes filters 416A to 416N, a radio frequency switch 417, and a low noise amplifier 418 according to an embodiment. One or more filters of the filters 416A to 416N can include any suitable number of acoustic wave resonators or packages in accordance with any suitable principles and advantages disclosed herein. Any suitable number of filters 416A to 416N can be implemented. The illustrated filters 416A to 416N are receive filters. In some embodiments (not illustrated), one or more of the filters 416A to 416N can be included in a multiplexer that also includes a transmit filter. The radio frequency switch 417 can be a multi-throw radio frequency switch. The radio frequency switch 417 can electrically couple an output of a selected filter of filters 416A to 416N to the low noise amplifier 418. In some embodiments (not illustrated), a plurality of low noise amplifiers can be implemented. The module 415 can include diversity receive features in certain applications.

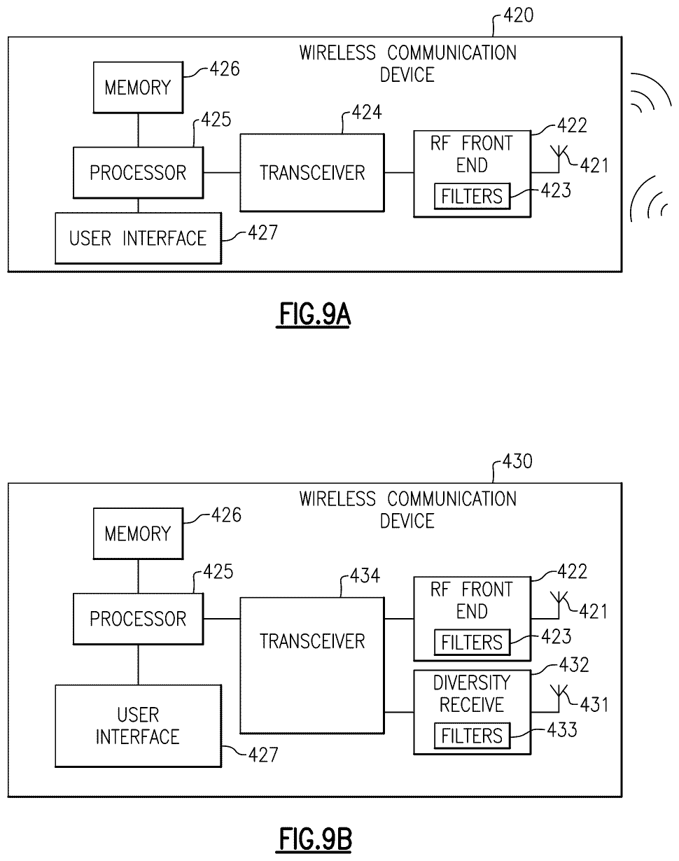

FIG. 9A is a schematic diagram of a wireless communication device 420 that includes filters 423 in a radio frequency front end 422 according to an embodiment. The filters 423 can include one or more SAW resonators or packages in accordance with any suitable principles and advantages discussed herein. The wireless communication device 420 can be any suitable wireless communication device. For instance, a wireless communication device 420 can be a mobile phone, such as a smart phone. As illustrated, the wireless communication device 420 includes an antenna 421, an RF front end 422, a transceiver 424, a processor 425, a memory 426, and a user interface 427. The antenna 421 can transmit/receive RF signals provided by the RF front end 422. Such RF signals can include carrier aggregation signals. Although not illustrated, the wireless communication device 420 can include a microphone and a speaker in certain applications.

The RF front end 422 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 422 can transmit and receive RF signals associated with any suitable communication standards. The filters 423 can include SAW resonators of a SAW component or package that includes any suitable combination of features discussed with reference to any embodiments discussed above.

The transceiver 424 can provide RF signals to the RF front end 422 for amplification and/or other processing. The transceiver 424 can also process an RF signal provided by a low noise amplifier of the RF front end 422. The transceiver 424 is in communication with the processor 425. The processor 425 can be a baseband processor. The processor 425 can provide any suitable base band processing functions for the wireless communication device 420. The memory 426 can be accessed by the processor 425. The memory 426 can store any suitable data for the wireless communication device 420. The user interface 427 can be any suitable user interface, such as a display with touch screen capabilities.

FIG. 9B is a schematic diagram of a wireless communication device 430 that includes filters 423 in a radio frequency front end 422 and filters 433 in a diversity receive module 432. The wireless communication device 430 is like the wireless communication device 420 of FIG. 9A, except that the wireless communication device 430 also includes diversity receive features. As illustrated in FIG. 9B, the wireless communication device 430 includes a diversity antenna 431, a diversity module 432 configured to process signals received by the diversity antenna 431 and including filters 433, and a transceiver 434 in communication with both the radio frequency front end 422 and the diversity receive module 432. The filters 433 can include one or more SAW resonators or packaged acoustic wave components that include any suitable combination of features discussed with reference to any embodiments discussed above.

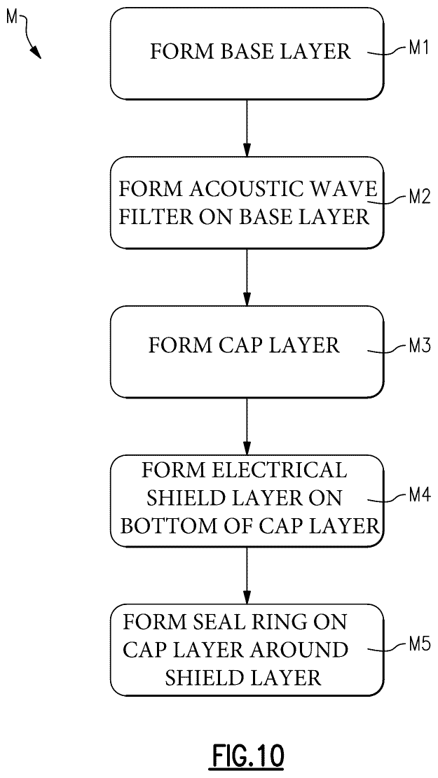

FIG. 10 illustrates a method M of making a packaged acoustic wave component (e.g., a multi-layer piezoelectric substrate (MPS) package or structure), such as the packaged acoustic wave component 100 or 200 in FIGS. 1A, 1B, 1C, and 2. The method M includes the step M1 of forming or providing a base layer (such as the base wafer 101). The method M further includes the step M2 of forming or providing an acoustic wave filter (such as the acoustic wave filter 104) disposed on an upper side of the base layer. The method M further includes the step M3 of forming or providing a cap layer (such as the cap wafer 110) for mounting to the upper side of the base layer such that a bottom side of the cap layer faces the upper side of the base layer. The method M further includes the step M4 of forming or providing an electrical shield layer (such as the electrical shield layer 112) disposed on the bottom side of the cap layer such that the electrical shield layer and the acoustic wave filter are positioned between the base layer and the cap layer.

Optionally, the method M can include the step M5 of forming or providing a seal ring (such as the seal ring 113) disposed on the bottom side of the cap layer around the electrical shield layer after the step M4 of forming or providing the electrical shield layer. Additionally, a support pillar can be formed or provided along the seal ring. In this way, an electrically conductive connection is provided between the seal ring of the base layer and the seal ring of the cap layer. Steps M1 and M3 could be performed at the same time. Steps M2 and M4 could also be performed at the same time.

In one implementation, a method of making a radio frequency module includes the steps above for method M in addition to forming or providing a package substrate and attaching additional circuitry and the packaged acoustic wave component to the MPS.

### APPLICATIONS

Although embodiments disclosed herein relate to surface acoustic wave resonators or packages and packaged acoustic wave components, any suitable principles and advantages disclosed herein can be applied to other types of acoustic wave resonators that include an IDT electrode, such as Lamb wave resonators and/or boundary wave resonators.

Some of the embodiments described above have provided examples in connection with wireless devices or mobile phones. However, the principles and advantages of the embodiments can be used for any other systems or apparatus that have needs for acoustic wave filters.

Such acoustic wave filters can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings provided herein can be applied to other systems, not necessarily the system described above. The elements and acts of the various embodiments described above can be combined to provide further embodiments.

While certain embodiments of the inventions have been described, these embodiments have been presented by way of example only and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A packaged acoustic wave component comprising:
a base layer;
an acoustic wave filter disposed on an upper side of the base layer;
a cap layer mounted to the upper side of the base layer such that a bottom side of the cap layer faces the upper side of the base layer; and
an electrical shield layer disposed on the bottom side of the cap layer such that the electrical shield layer and the acoustic wave filter are positioned between the base layer and the cap layer.

2. The packaged acoustic wave component of claim 1 wherein the base layer is configured as a base wafer.

3. The packaged acoustic wave component of claim 1 wherein the cap layer is configured as a cap wafer.

4. The packaged acoustic wave component of claim 1 further comprising a seal ring disposed on the bottom side of the cap layer around the electrical shield layer.

5. The packaged acoustic wave component of claim 4 wherein the seal ring of the cap layer and the electrical shield layer are made of the same material.

6. The packaged acoustic wave component of claim 4 wherein the seal ring of the cap layer is made of copper.

7. The packaged acoustic wave component of claim 4 wherein the seal ring of the cap layer is electrically connected to the electrical shield layer.

8. The packaged acoustic wave component of claim 1 further comprising a seal ring disposed on the upper side of the base layer around the acoustic wave filter.

9. The packaged acoustic wave component of claim 8 wherein the seal ring of the base layer is electrically connected to the acoustic wave filter.

10. The packaged acoustic wave component of claim 1 further comprising a support pillar coupling the seal ring of the base layer with the seal ring of the cap layer.

11. The packaged acoustic wave component of claim 1 wherein the cap layer comprises at least one of silicon, quartz, glass, spinel, or sapphire.

12. The packaged acoustic wave component of claim 1 wherein the electrical shield layer is formed as a grid pattern.

13. The packaged acoustic wave component of claim 1 wherein the acoustic wave filter is configured as one of a surface acoustic wave (SAW) filter or a temperature compensated surface acoustic wave (TCSAW) filter.

14. The packaged acoustic wave component of claim 1 wherein the acoustic wave filter is configured as a bulk acoustic wave (BAW) filter.

15. A radio frequency module including a packaged acoustic wave component, the packaged acoustic wave component comprising:
a base layer;
an acoustic wave filter disposed on an upper side of the base layer;
a cap layer mounted to the upper side of the base layer such that a bottom side of the cap layer faces the upper side of the base layer; and
an electrical shield layer disposed on the bottom side of the cap layer such that the electrical shield layer and the acoustic wave filter are positioned between the base layer and the cap layer.

16. The radio frequency module of claim 15 wherein the radio frequency module is configured as a front end module.

17. A wireless communication device comprising a radio frequency module including a packaged acoustic wave component, the packaged acoustic wave component including a base layer, an acoustic wave filter disposed on an upper side of the base layer, a cap layer mounted to the upper side of the base layer such that a bottom side of the cap layer faces the upper side of the base layer, and an electrical shield layer disposed on the bottom side of the cap layer such that the electrical shield layer and the acoustic wave filter are positioned between the base layer and the cap layer.

18. The wireless communication device of claim 17 further comprising an antenna operatively coupled to the acoustic wave filter, a radio frequency amplifier operatively coupled to the radio frequency module and configured to amplify the radio frequency signal, a transceiver in communication with the radio frequency amplifier, and a baseband processor in communication with the transceiver.

19. A method of making a packaged acoustic wave component, the method comprising:
forming a base layer;
forming an acoustic wave filter disposed on an upper side of the base layer;
forming a cap layer for mounting to the upper side of the base layer such that a bottom side of the cap layer faces the upper side of the base layer; and
forming an electrical shield layer disposed on the bottom side of the cap layer such that the electrical shield layer and the acoustic wave filter are positioned between the base layer and the cap layer.

20. The method of making a packaged acoustic wave component of claim 19 further comprising forming a seal ring disposed on the bottom side of the cap layer around the electrical shield layer after forming or providing the electrical shield layer.
